(19) United States
(12) Patent Application Publication
(10) Pub. No.: US 2011/0107473 A1
(43) Pub. Date: May 5, 2011

(54) DIAMOND-LIKE CARBON COATED NANOPROBES

(75) Inventors: Robert W. Carpick, Philadelphia, PA (US); Kumar Sridharan, Madison, WI (US); Anirudha V. Sumant, Downers Grove, IL (US)

(73) Assignee: Wisconsin Alumni Research Foundation

(21) Appl. No.: 11/686,046

(22) Filed: Mar. 14, 2007

Related U.S. Application Data
(60) Provisional application No. 60/782,575, filed on Mar. 15, 2006.

(51) Int. Cl. G01Q 70/14; C23C 14/06; C23C 14/48; B82Y 40/00; B82Y 35/00

(52) U.S. Cl. 850/59; 427/523; 427/527; 977/832; 977/891

(57) ABSTRACT

Diamond-like carbon (DLC) coated nanoprobes and methods for fabricating such nanoprobes are provided. The nanoprobes provide hard, wear-resistant, low friction probes for use in such applications as atomic force microscopy, nanomachining, nanotribology, metrology and nanolithography. The diamond-like carbon coatings include a carbon implantation layer which increases adhesion of a deposited DLC layer to an underlying nanoprobe tip.

### CROSS-REFERENCE TO RELATED APPLICATION

This application claims the benefit of provisional patent application No. 60/782,575, filed Mar. 15, 2006, the disclosure of which is incorporated herein by reference.

### STATEMENT OF GOVERNMENT RIGHTS

Research funding was provided for this invention by the Department of Energy under grant number DE-FG07-025F22617 and by the Air Force Office of Scientific Research under grant number FA 9550-05-1-0204. The United States government has certain rights in this invention.

### FIELD OF THE INVENTION

This invention relates to nanoprobes coated with diamond-like carbon for use in applications such as scanning probe microscopy, nanomachining, nanotribology, nanolithography, metrology, and nanolithography.

### BACKGROUND

Tips of silicon or silicon nitride tapered down to a few atomic diameters have been used in Atomic Force Microscopes (AFM) for many years to image materials on an atomic scale. imaging hard or adhesive materials remains an ongoing challenge. As well, with the emergence of the field of nanotechnology, AFM tips are being considered for applications as active devices for nanofabrication and nanomechanical data storage. The nanometer-scale precision and size of these tips naturally lends itself to these future nanotechnologies. However, an important limitation towards achieving this goal is the tip material itself, which thus far is limited to a few materials such as silicon and silicon nitride. To make these AFM tips effective tools for future nanotechnologies, the AFM tips themselves must be coated with a film of a material with superior properties as defined by the application of interest. Five factors then become paramount in the deposition process and commercialization: (i) the film has to be thin (<50 nm, preferably ˜10 nm or even less) in order to retain the small size of the AFM tip, (ii) the film has to be conformal throughout the tip contour and also be atomically smooth so as to not compromise the geometrical integrity of the tip, (iii) the deposition process should be capable of depositing films of non-conventional materials with desired properties, (iv) the deposition is preferably be carried out at or near room temperature to minimize distortion and dimensional changes, and (v) deposition should be commercially viable in terms of coating large number (thousands at a time) such tips in short times. Furthermore, it is desirable that the tips be mechanically robust with low intrinsic friction to reduce wear, and chemically inert to reduce adhesive interactions.

### SUMMARY OF THE INVENTION

Diamond-like carbon (DLC) coated nanoprobes and methods for fabricating such nanoprobes are provided. The coated nanoprobes provide hard, wear-resistant, low friction probes for use in such applications as atomic force microscopy, nanomachining, and nanolithography. The diamond-like carbon films have the option of including a carbon implantation layer which increases adhesion of a deposited DLC layer to an underlying nanoprobe tip.

The nanoprobes include a cantilever arm (which may have a variety of shapes and sizes) and a nanoprobe tip extending outwardly from a surface of the cantilever arm. The nanoprobe tip may be integrated with the cantilever arm. In some embodiments, the entire nanoprobe tip is coated by a DLC film. DLC films having thicknesses of 50 nm or less may be formed on the nanoprobe tips. In some embodiments, coated nanoprobe tips having tip radii (including the coating) of no more than about 5 nm may be fabricated by the methods disclosed herein. The present DLC film are well-suited for use on silicon and silicon nitride nanoprobe tips, and are generally applicable to other nanoprobe materials.

The deposited DLC layers may be doped layers. Dopants, such as silicon and fluorine may be used to alter the properties, such as electrical conductivity, surface energy, hardness, friction, and elastic modulus of the films, making them useful for applications such as scanning capacitance microscopy, electrochemical scanning probe studies, nanomachining of hard materials, nanotribology, and studies of biofunctionalized materials. The dopants are desirably elements that increase the wear-resistance and/or thermal stability of the coating relative to an undoped coating. The silicon-doped DLC films have excellent thermal stability, up to temperatures of 300° C., or even higher, making them useful for applications where elevated temperature operation is required. Undoped forms of DLC are not stable at these temperatures. Therefore, prior to this invention, DLC was not considered a suitable coating for nanostructures that require elevated temperature operation.

The DLC coated nanoprobes may be fabricated by forming a carbon implantation layer in the surface of a nanoprobe tip and a deposited DLC layer over the carbon implantation layer using plasma immersion ion implantation and deposition (PIIID). Advantageously, the PIIID process may be carried out quickly (e.g., in less than 5 minutes) and may be used to coat large number (e.g., thousands) of nanoprobes simultaneously. No heating of the nanoprobe is required to achieve such deposition. The PIIID process is generally carried out as follows. A nanoprobe is immersed in a plasma of a gas containing a carbon-containing deposition species in a vacuum chamber and biased to a negative potential (A doped DLC film may be formed by using a plasma of a gas containing a dopant-containing deposition species.) As a result, positively charged ions in the plasma are accelerated at high velocities toward the nanoprobe. High energy ions are implanted into the surface of the nanoprobe while lower energy ions lead to the decomposition of reactant gas radicals resulting in deposition of a DLC layer from condensable plasma species. Thus, the carbon implantation layer is made from the portion of the nanoprobe surface into which carbon atoms have been implanted. This layer generally takes the form of a graded layer with a carbon content that decreases with increasing depth into the nanoprobe tip. Typically, this carbon implantation layer has a depth of about 5 to about 50 nm, depending on the energy used. The PIIID process is inherently non-line-of-sight in nature and allows for uniform surface treatment of the three-dimensional nanoprobes without the necessity of nanoprobe manipulation in the vacuum chamber during surface treatment.

In one preferred embodiment, PIIID is used to deposit a Si-doped DLC film on a nanoprobe tip. In some such embodiments the Si-doped DLC film has a surface composition comprising at least about 15 atomic percent Si, based on the total silicon, oxygen and carbon content of the surface.

Further objects, features and advantages of the invention will be apparent from the following detailed description when taken in conjunction with the accompanying drawings.

### BRIEF DESCRIPTION OF THE DRAWINGS

FIG. 1 a schematic diagram of an apparatus that may be used to produce a DLC coated nanoprobe in accordance with the present invention.

FIG. 2(a) and (b) show TEM images of silicon AFM tips coated with DLC films.

### DETAILED DESCRIPTION OF THE INVENTION

The present invention provides DLC and doped-DLC coated nanoprobes and to methods for making the coated nanoprobes. DLC is amorphous with no long range order. The carbon in DLC is present in both the hybridized sp³ (diamond) and sp² (graphite) bonding configurations. The sp³/sp² ratio, which strongly influences DLC film properties, depends on the hydrogen content of the film and deposition parameters such as pressure, ion impingement energy and the surface power density of the substrate. The films are generally known for their high hardness, low friction, chemical inertness, biocompatibility, hydrophobicity, high electrical resistivity, and high transparency to visible and infrared wavelengths.

One aspect of the invention provides DLC coated nanoprobes. The DLC coated nanoprobes may be formed by first creating a carbon implantation layer in the surface of a pre-fabricated nanoprobe to promote bonding between the DLC and the nanoprobe. Then, the DLC layer is deposited over this implantation layer. Alternatively, the DLC film may be deposited directly onto the nanoprobe. Typical materials for the pre-fabricated nanoprobe tip include silicon and silicon nitride. In some embodiments, the DLC film may have a thickness of no greater than about 10 nm. This includes embodiments where the film has a thickness of no greater than about 5 nm, or even not greater than about 3 nm. Depending on the initial radius of the pre-fabricated nanoprobe tips, DLC coated tips having tip radii (i.e., the radii at the distal end of the tip, including the DLC film) of no greater than about 50 nm may be formed. This includes embodiments where the tip radius is no more than about 30 nm and further includes embodiments where the tip radius is no more than about 10 nm. The use of thin Si-doped DLC films on nanoprobes is advantageous because the DLC films are thermally stable and, therefore, may be used as a coating on nanoprobes having embedded heaters.

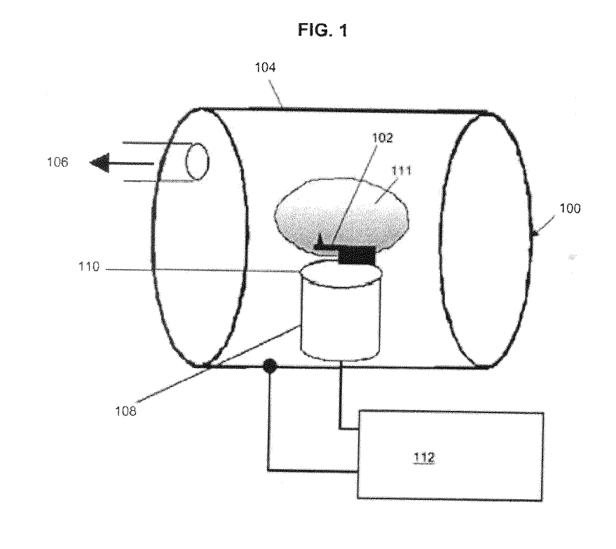

One specific example of a method for producing Si-doped DLC films on silicon nanoprobes is described in conjunction with FIG. 1, which shows a schematic diagram of a plasma apparatus 100. In this example, a silicon nanoprobe (AFM tip) 102, having dimensions of ˜70 μm long, with a tip 500-700 nm long, was placed in a plasma chamber 104. The chamber may be pumped down using a turbo molecular pump 106. The nanoprobe 102 is mounted on a platform that includes an insulating base 108 and a biased stage 110. The DLC film was deposited using a plasma 111 of acetylene precursor gas at a pressure of about 10 mTorr and a stage voltage bias of about −3 kV using a high voltage pulser 112. The Si-doped DLC films were deposited using a plasma of hexa-methyl disiloxane precursor gas under similar conditions. The nanoprobes were maintained at room temperature during film deposition by the flow of coolant oil through the nanoprobe stage. The thickness of the DLC film was in the range of 5 to 60 nm.

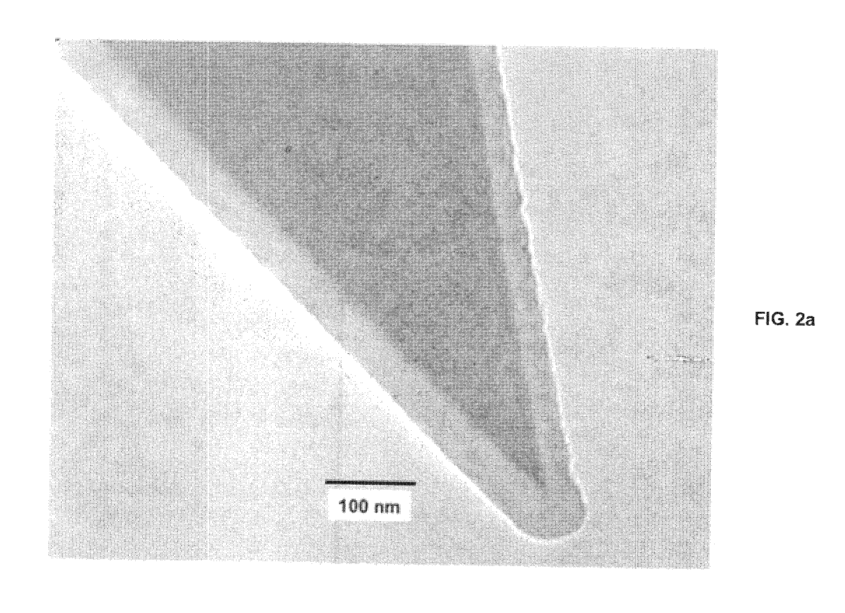

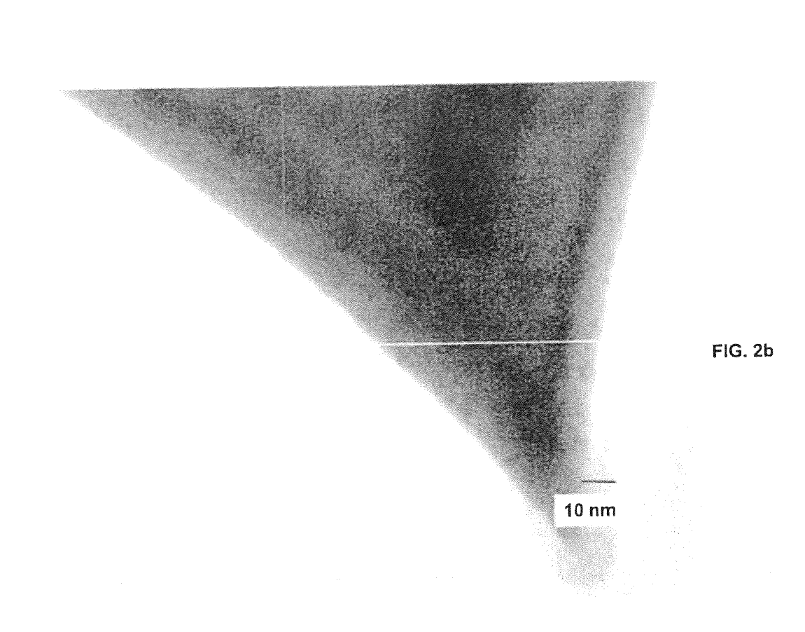

Transmission electron microscopy (TEM) was used to characterize the DLC films. FIG. 2(a) and (b) show TEM images of DLC films on silicon nanoprobes. As shown in the figure, the coatings are continuous, substantially uniform and smooth down to an atomic level. The coating shown in FIG. 2(a) has a thickness of about 50 nm and is an undoped DLC film. The coating in FIG. 2(b) has a thickness of about 10 nm and is a Si-doped DLC film.

The nanoprobe tips may be used in a variety of applications, but are particularly useful in applications where wear-resistance and thermal stability is important. One such application is contact atomic force microscopy. Another such application is nanolithography, particularly dip-pen or fountain pen lithography. Other suitable applications include, but are not limited to, scanning spreading resistance microscopy, atomic-scale potentiometry, nanotribology, and scanning thermal microscopy.

A high capacity storage system which uses an array of nanoprobe tips to read and write bits on a thin polymer film is an example of a suitable use for the present nanoprobes. In such systems, a dense, two dimensional array of 1000 or more nanoprobes are used to create nano-scale depressions in a thin polymer film, typically coating a thin silicon substrate. The nanoprobes for use in this application desirably include a heating element coupled to, or integrated with, the nanoprobe. By heating the nanoprobe tips, the polymer film may be softened, allowing the tips to penetrate its surface, creating indentations (or bits) in the film. The nanoprobes for use in these systems desirably have cantilever arms with cross-sectional diameters of no more than about 1 μm, desirably no more than about 0.5 pm and lengths of no more than about 100 μm, desirably no more than about 75 μm.

Functionalized nanoprobes may also be used to detect chemical or biochemical species on a surface, or to measure chemical or biochemical interactions between functional groups on a nanoprobe tip and functional groups on a surface over which the nanoprobes are scanned. For example, a nanoprobe tip may be functionalized with a biomolecule which interacts with (e.g., hybridizes with) another biomolecule of interest. When the functionalized nanoprobe is scanned over a surface having (or suspected of having) the biomolecule of interest associated with it, interactions between the two biomolecules may be detected or measured (e.g., by detecting a deflection in the cantilever arm). Biomolecules for use in the functionalization of (and the detection by) the nanoprobes of the present invention are well-known in the art. Suitable biomolecules include, but are not limited to, biomolecules independently selected from the group consisting of oligonucleotide sequences, including both DNA and RNA sequences, amino acid sequences, proteins, protein fragments, ligands, receptors, receptor fragments, antibodies, antibody fragments, antigens, antigen fragments, enzymes and enzyme fragments. Thus, the biomolecular interactions that may be studied include, but are not limited to, receptor-ligand interactions (including protein-ligand interactions), hybridization between complementary oligonucleotide sequences (e.g. DNA-DNA interactions or DNA-RNA interactions), and antibody-antigen interactions. The DLC coated nanoprobes may be functionalized according to the methods disclosed in U.S. Patent Application Publication No. 2005/0214535, the entire disclosure of which is incorporated herein by reference.

For the purposes of this disclosure and unless otherwise specified, “a” or “an” means “one or more”. All patents, applications, references and publications cited herein are incorporated by reference in their entirety to the same extent as if they were individually incorporated by reference.

While the principles of this invention have been described in connection with specific embodiments, it should be understood clearly that these descriptions are made only by way of example and are not intended to limit the scope of the invention.

What is claimed is:

1. A coated pre-fabricated nanoprobe comprising a cantilever arm, a nanoprobe tip extending outwardly from the cantilever arm, and an electrically insulating diamond-like carbon film coating at least a portion of the nanoprobe tip, the diamond-like carbon film comprising an implanted carbon layer and a deposited carbon-based layer.

2. The nanoprobe of claim 1, wherein the diamond-like carbon film has a thickness of no more than about 50 nm.

3. The nanoprobe of claim 1, wherein the diamond-like carbon film has a thickness of no more than about 20 nm.

4. The nanoprobe of claim 1, wherein the diamond-like carbon film is a doped diamond-like carbon film.

5. The nanoprobe of claim 4, wherein the doped diamond-like carbon film is a silicon-doped film.

6. The nanoprobe of claim 5, wherein the surface of the silicon-doped diamond-like carbon film comprises at least about 15 atomic percent Si.

7. The nanoprobe of claim 1, wherein the nanoprobe further comprises an embedded heating element.

8. The nanoprobe of claim 1, wherein the nanoprobe tip comprises silicon.

9. The nanoprobe of claim 1, wherein the nanoprobe tip comprises silicon nitride.

10. An array of nanoprobes comprising a plurality of the nanoprobes of claim 1 arranged in an array.

11. A method of fabricating a diamond-like carbon coated nanoprobe comprising a cantilever arm and a nanoprobe tip, the method comprising forming a carbon implantation layer in the surface of the nanoprobe tip and depositing a diamond-like carbon film over the surface of the nanoprobe tip using plasma immersion ion implantation deposition.

12. The method of claim 11, wherein the diamond-like carbon film has a thickness of no more than about 50 nm.

13. The method of claim 11, wherein the diamond-like carbon film has a thickness of no more than about 20 nm.

14. The method of claim 11, wherein the diamond-like carbon film is a doped diamond-like carbon film.

15. The method of claim 14, wherein the doped diamond-like carbon film is a silicon-doped film.

16. The method of claim 15, wherein the surface of the silicon-doped diamond-like carbon film comprises at least about 15 atomic percent Si.

17. The method of claim 11, wherein the nanoprobe tip comprises silicon.

18. The method of claim 11, wherein the nanoprobe tip comprises silicon nitride.
